(19) United States
(12) Patent Application Publication
(10) Pub. No.: US 2008/0246637 A1
(43) Pub. Date: Oct. 9, 2008

(54) Cabac Decoding Method

(75) Inventors: Jian Wen Chen, Kaohsiung County (TW); Youn Long Lin, Hsinchu (TW)

Correspondence Address: WPAT, PC;INTELLECTUAL PROPERTY ATTORNEYS, 2030 MAIN STREET, SUITE 1300, IRVINE, CA, 92614, US

(73) Assignee: NATIONAL TSING HUA UNIVERSITY, Hsinchu (TW)

(21) Appl. No.: 11/863,973

(22) Filed: Sep. 28, 2007

(30) Foreign Application Priority Data
Apr. 3, 2007 (TW) 096111738

(51) Int. Cl. H03M 7/00

(52) U.S. Cl. 341/51

(57) ABSTRACT

A decoding method of CABAC is proposed. A CABAC decoder comprises an arithmetic engine performing two arithmetic decodings for a coefficient or reading contexts at the same time in a clock cycle. The arithmetic decoding for a coefficient comprises the steps of: (1) providing a residual block comprising Significant_flags, Last_significant_flags, coefficients and the corresponding contexts; (2) sequentially resolving the Significant_flag and the Last_significant_flag of a non-zero coefficient; and (3) decoding the non-zero coefficient to obtain regular bins and bypass bins, wherein the arithmetic decoding is conducted twice in a clock cycle.

### BACKGROUND OF THE INVENTION

(A) Field of the Invention

The present invention relates to a video decoding method, and more specifically, to a decoding method of context-based adaptive binary arithmetic coding (CABAC).

(B) Description of the Related Art

H.264/AVC is the latest video coding standard developed by the ITU-T Video Coding Experts Group and ISO/IEC Moving Picture Experts Group. It has several new features including multiple reference frames and variable block size motion estimation, integer DCT, in-loop deblocking filter, and context-based adaptive binary arithmetic coding (CABAC). In comparison with MPEG-4, CABAC can achieve up to 50% bit-rate saving under the same video quality constraint.

CABAC is one of two entropy coding methods in H.264/AVC, and the arithmetic decoding is shown in FIG. 1, a context table including contexts which are calculated according to reference data. The context table includes contexts, Most Probable Symbols (MPS) and probability index (pState). The pState is between 0 and 63, and the larger number means that there is a higher probability of the occurrence of 0/1. Sequentially, an arithmetic decoding is performed, and if the decoding result is too small, renormalization is performed to return the value back to normal. If estimated arithmetic decoding is 1 and the operating result is the same, the pState is increased, i.e., transIdxMPS table is used to update the context table. If the result is not equal to the estimated value, the pState is decreased, i.e., transIdxLPS table is used to update the context table.

Compared to another method named context-based adaptive variable length coding (CAVLC), CABAC saves more than 7% of bit-rate at the expense of higher computation complexity. Profiling results show that CABAC consumes about 10% of total decoding time. Therefore, accelerating the CABAC decoding with hardwired implementation is desirable for high-performance or low-power applications.

### SUMMARY OF THE INVENTION

According to an analysis of decoding times for different types of syntax elements, the present invention provides a highly efficient CABAC decoding method by decreasing the decoding cycles.

According to the present invention, a decoding method of CABAC decoder comprises an arithmetic engine performing two arithmetic decodings for coefficient, Significant, and Last_significant bins and proposed a novel context memory architecture to read contexts at the same time in a clock cycle.

More specifically, the arithmetic decoding for a coefficient comprises the steps of: (1) providing a residual block comprising Significant_flags, Last_significant_flags, coefficients and the corresponding contexts; (2) sequentially resolving the Significant_flag and the Last_significant_flag of a non-zero coefficient; and (3) decoding the non-zero coefficient to obtain regular bins and bypass bins, wherein the arithmetic decoding is conducted once or twice bins in a clock cycle.

Reading contexts at the same time comprises the steps of: (1) providing a video block comprising Significant_flags, Last_significant_flags, coefficients and the corresponding contexts; (2) rearranging a context table corresponding to the plurality of contexts to a first context table and a second context table, the first context table comprising Significant_flags of the contexts and the second context table comprising Last_significant_flags of the contexts; and (3) simultaneously reading contexts corresponding to the Significant_flags and the Last_significant_flags for decoding.

### BRIEF DESCRIPTION OF THE DRAWINGS

The objectives and advantages of the present invention will become apparent upon reading the following description and upon reference to the accompanying drawings in which:

FIG. 1 shows a known CABAC arithmetic decoding;

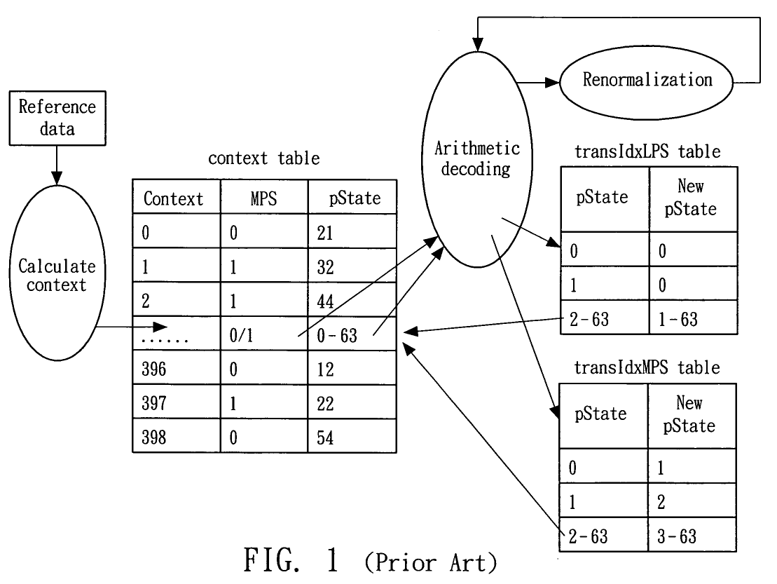

FIG. 2 shows the decoding order of a residual block in accordance with an embodiment of the present invention;

FIG. 3 shows the result of the arithmetic decoding of the residual block of FIG. 2;

FIG. 4 shows an arithmetic block diagram of CABAC in accordance with the present invention;

FIG. 5 shows a CABAC decoding method in accordance with an embodiment of the present invention; and

FIG. 6 shows another CABAC decoding method in accordance with an embodiment of the present invention.

### DETAILED DESCRIPTION OF THE INVENTION

The CABAC decoding method of the present invention is illustrated with reference to the appended drawings.

Table 1 shows a data distribution of different syntax elements (SE). According to the bin numbers in Table 1, Coded_block_flag, Coefficient, Significant_flag and Last_significant_flag (Sig. & Last_sig. pair) occupy around 80% of the total data and, in particular, they occupy 90% in I macroblock. In addition, the data rate of I macroblock is more than 3 times that of P and B macroblock. The present invention exists mainly to increase the decoding efficiency of I macroblock.

TABLE 1

| Types of Syntax | | | | | |
|---|---|---|---|---|---|
| element | | Coded_block_flag | Coefficient | Sig. & Last_sig. | Others |
| 1 MB | Bin number | 22 | 319 | 259 | 52 |
| | Distribution | 3.3% | 49% | 39.7% | 8% |
| P | Bin number | 10 | 44 | 76 | 35 |
| MB | Distribution | 6% | 26.7% | 46% | 21.2% |
| B | Bin number | 5 | 31 | 16 | 26 |
| MB | Distribution | 6.4% | 39.7% | 20.5% | 33.3% |

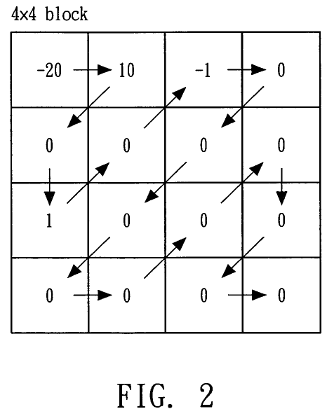

H.264/AVC partitions one macroblock into 24 “4×4 residual blocks.” FIG. 2 shows the CABAC decoding order of a 4×4 residual block. In the beginning, the decoder sorts the 4×4 residual block according to a Zig-Zag scanning as the arrow signs indicate. In this embodiment, the decoding order is −20, 10, 0, 1, 0, −1, 0, 0, etc.

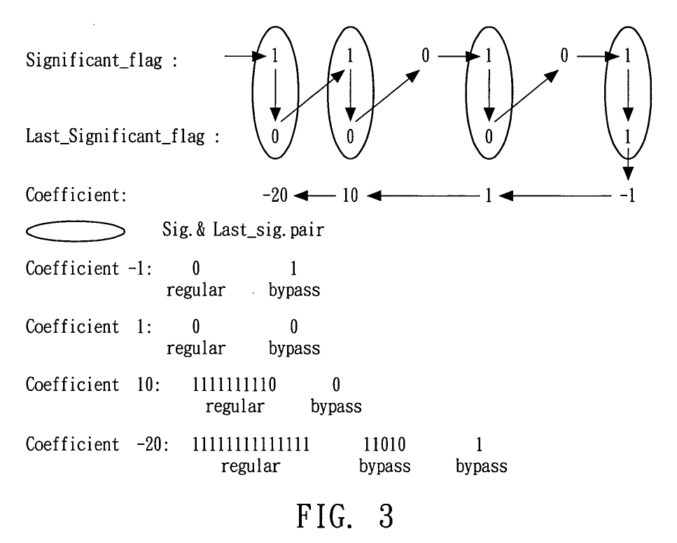

Referring to FIG. 3, Significant_flag is “1” if the decoded value is not equal to zero, and in contrast Significant_flag is “0” if the decoded value is zero. Last_significant_flag is “0” if the coefficient is not the last non-zero coefficient; otherwise Last_significant_flag is equal to “1”. Therefore, the coefficient “−20” has Significant_flag of “1” and Last_significant_flag of “0”. The coefficient “−10” has Significant_flag of “1” and Last_significant_flag of “0”. The coefficient “0” has Significant_flag of “0”. The coefficient “1” has Significant_flag of “1” and Last_significant_flag of “0”. The coefficient “−1” has Significant_flag of “1” and Last_significant_flag of “1”. Because the values after the Last_significant_flag of “1” in the 4×4 residual block are equal to zero, they need not be considered while decoding. According to the analysis of FIG. 3, there are on average 6 Significant_flags and 4 Last_significant_flags in one 4×4 block, and a Significant_flag and a Last_significant_flag form a Significant and Last_significant flag pair (Sig. & Last_sig. Pair) as indicated by a circle.

After Significant_flag and Last_significant_flag are resolved, the non-zero coefficients mapped to Sig. & Last_sig. Pair are obtained, and they are −1, 10, −20 in order. CABAC decoder presents the coefficient value by unary and 0th order Exp-Golomb Scheme and indicates the sign of coefficient by a Sign_flag syntax element. The decoded coefficient includes a regular portion of the prefix part and the following bypass portion of sign flag. If the coefficient is negative, the value of a Sign_flag is equal to 1. If the coefficient is positive, the value is equal to 0.

The present invention proposes two methods to reduce clock cycles for decoding syntax elements of coefficient, and Sig. & Last_sig. Pair, respectively.

### Two-Bin-Per-Cycle Decoding Method

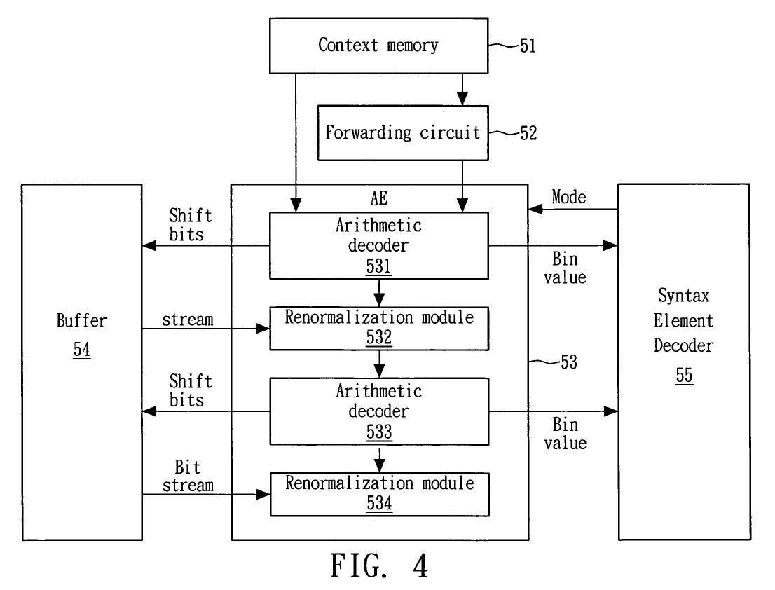

The CABAC decoder uses 41% of total cycles to decode Coefficient SE. Therefore, the present invention proposes a two-bin-per-cycle method as depicted in FIG. 4 to decode two bins in one clock cycle, so as to increase the decoding efficiency of coefficient syntax elements.

A context memory 51 transfers context data to an arithmetic engine 53 through a forwarding circuit 52. The forwarding circuit 52 is configured to avoid reading non-updated context data when decoding a sequence of bins with the same context. The arithmetic engine 53 includes two arithmetic decoders 531 and 533 and two renormalization modules 532 and 534. The arithmetic decoder 531, the renormalization module 532, the arithmetic decoders 533 and the renormalization module 534 are connected in series. The arithmetic decoders 531 and 533 transmit bin values to a syntax element decoder and the number of shift bits to a buffer 54. The buffer 54 transmits the bit streams to the renormalization modules 532 and 534.

The arithmetic engine 53 includes the two arithmetic decoders 531 and 533, so that two regular bins, two bypass bins or a regular bin and a bypass bin can be decoded in a clock cycle.

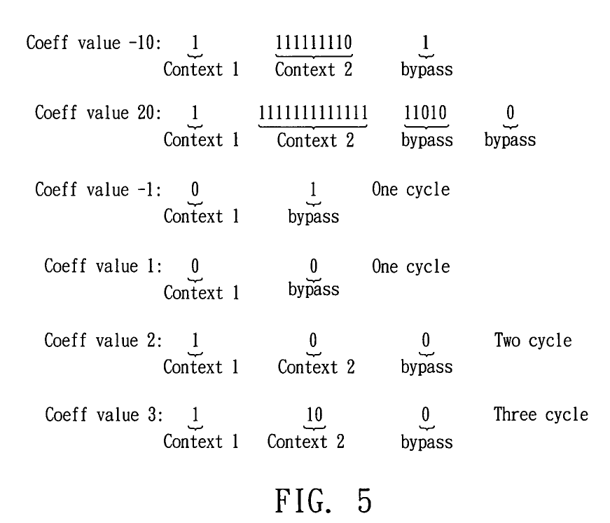

Referring to FIG. 5, Context 1 and Context 2 are regular modes. According to empirical data, the percentage of coefficient value equal to 1 or −1 is higher than 60%. Therefore, the first bin for decoding is assumed to be “0.” If the assumption is correct, the only step needed to complete the decoding is to further identify whether the coefficient is positive or negative. Because the present invention uses two arithmetic decoders for decoding, the coefficient equal to 1 or −1 only needs a clock cycle to complete the decoding.

If the first bin is not equal to 0, the empirical data shows that the percentage of the coefficient equal to 2 or −2 is around 20%. Therefore, the second bin equal to 0 has higher probability, and the second bin is assumed to be 0, which is still under regular mode. If the coefficient is equal to 2, it needs two clock cycles including a cycle for decoding the first bin and a cycle for decoding the second bin and Sign_flag bin to complete decoding.

If the coefficient is equal to 3, it needs three clock cycles to complete the decoding, including a cycle for decoding the first bin, a cycle for decoding the second and the third bins, and a cycle for decoding the Sign_flag bin.

In other words, a regular together with a bypass can be decoded by assuming that the second bin is bypass mode. Therefore, if the coefficient is equal to “1” or “−1”, only a clock cycle is needed for decoding.

Referring to Table 2, the present invention in comparison with the prior art can effectively reduce the clock cycles for coefficient decoding. Taking into account control overhead and stall due to buffer emptiness, the proposed two-bin-per-cycle method contributes 13% reduction of total cycles.

TABLE 2

| | Clock Cycle | Clock Cycle |
|---|---|---|
| Coefficient | (the present invention) | (the prior art) |
| +/−1 | 1 | 2 |
| +/−2 | 2 | 3 |
| +/−3 | 3 | 4 |
| +/−4 | 3 | 5 |
| +/−5 | 4 | 6 |

The above embodiment performs two coefficient decodings in one clock cycle. However, the applications with other numbers of coefficient decodings and based on the same concepts are also covered by the present invention.

### The Rearrangement of Context Table Method

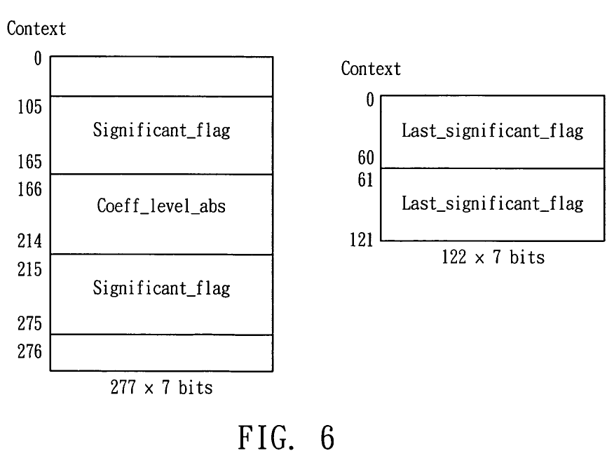

According to empirical analysis, there are on the average 6 Significant_flags and 4 Last_significant_flags in one 4×4 block. Their decoding accounts for 31.7% of the total time. The context table is divided into two tables as shown in FIG. 6. The context data of the Significant_flags and absolute Coefficient values (Coeff_level_abs) are placed in the first Context table, and that of the Last_Significant_flags are placed in the second Context table. Accordingly, the CABAC decoder of the present invention can read the context data of the Significant_flag and Last_Significant_flag in parallel and thereby increase the reading efficiency. Therefore, the CABAC decoder can decode Sig. & Last_sig. Pair in one cycle using our proposed arithmetic engine.

By the rearrangement of context tables, the proposed CABAC decoder saves 12% of total cycles after taking into consideration stall due to buffer emptiness.

In an embodiment, 309 clock cycles are used to decode a typical I-type macroblock. It needs to run at only 45 MHz for 1080 HD application.

The above-described embodiments of the present invention are intended to be illustrative only. Numerous alternative embodiments may be devised by those skilled in the art without departing from the scope of the following claims.

What is claimed is:

1. A decoding method of context-based adaptive binary arithmetic coding (CABAC) decoder, the CABAC decoder comprising an arithmetic engine performing two arithmetic decodings for a coefficient and Significant and Last significant pair in a clock cycle.

2. The decoding method of CABAC of claim 1, wherein the arithmetic decoding for a coefficient comprises:
providing a residual block comprising Significant flags, Last significant flags, coefficients and the corresponding contexts;
sequentially resolving the Significant flag and Last significant flag of a non-zero coefficient; and
decoding the non-zero coefficient to obtain regular bins and bypass bins.

3. The decoding method of CABAC of claim 2, wherein the first regular bin of the coefficient is preset to 0.

4. The decoding method of CABAC of claim 3, wherein the second regular bin is preset to 0 if the first regular bin is not 0.

5. The decoding method of CABAC of claim 2, wherein the two arithmetic decodings resolve two regular bins, two bypass bins, or a regular bin and a bypass bin.

6. The decoding method of CABAC of claim 1, wherein reading contexts at the same time comprises:
providing a residual block comprising a plurality of contexts;
rearranging a context table corresponding to the plurality of contexts to a first context table and a second context table, the first context table comprising Significant flags of the contexts and the second context table comprising Last significant flags of the contexts; and
simultaneously reading contexts corresponding to the Significant flags and the Last significant flags for decoding.

7. The decoding method of CABAC of claim 1, which is used for decoding I-macroblocks.
